(19) United States
(12) Patent Application Publication
(10) Pub. No.: US 2007/0048895 A1
(43) Pub. Date: Mar. 1, 2007

(54) Method of manufacturing an organic electronic device

(76) Inventors: Mitsuru Suginoya, Chiba-shi (JP); Shuhei Yamamoto, Chiba-shi (JP); Masayuki Suda, Chiba-shi (JP)

Correspondence Address: BRUCE L. ADAMS, ESQ., SUITE 1231, 17 BATTERY PLACE, NEW YORK, NY, 10004, US

(21) Appl. No.: 11/341,799

(22) Filed: Jan. 27, 2006

(30) Foreign Application Priority Data
Feb. 4, 2005 (JP) 2005-029321

(51) Int. Cl. H01L 51/40

(52) U.S. Cl. 438/99

(57) ABSTRACT

An organic electronic device using an extremely thin substrate is manufactured by a simple and easy method. That is, according to the method of manufacturing the organic electronic device of the present invention, a first surface of a substrate is subjected to polishing, a protective layer is provided on the first surface, and a second surface on the back side of the first surface of the substrate is removed through etching to reduce the thickness of the substrate. As a result, the extremely thin substrate may be formed. Two extremely thin substrates manufactured through the above process are arranged such that etching surfaces thereof are opposed to each other. Then, the two substrates are bonded to each other so as to hold a layer containing a polymer material therebetween. Thereafter, the protective layer is removed. Accordingly, the organic electronic device is formed on the first surface from which the protective layer has been removed.

### BACKGROUND OF THE INVENTION

1. Field of the Invention

The present invention relates to a method of manufacturing an organic electronic device that employs a flexible substrate, for example, an organic EL light emitting device or organic semiconductor device.

2. Description of the Related Art

In a recent proposed ubiquitous society, organic electronic devices that employ a flexible substrate have been expected as ones applicable to ubiquitous electronic equipment that supports the proposed ubiquitous society. Of those, an organic EL light emitting device can provide light emission at a lower voltage than that of an inorganic EL element. Further, the organic EL light emitting device is of a self light emission type, thereby being capable of providing high visibility. Employment of the flexible substrate enhances the applicability of the organic EL light emitting devices to a display or light emitting source for the ubiquitous electronic equipment.

However, a polymer material, which is often used for the flexible substrate is composed of an organic material. So, the flexible substrate made of the polymer material has moisture permeability slightly but in most cases. The organic electronic devices including the organic EL light emitting device often deteriorate due to even a minute amount of moisture to lose characteristics thereof. In the case where a polymer is used for the substrate of the organic electronic device, the big challenge to commercialization is to cut off the moisture that penetrates through the substrate.

In view of the above, for example, JP 11-329715 A discloses a method of using a substrate obtained by combining an extremely thin glass substrate with a polymer film as an effective method for solving the above-described challenge. The glass substrate itself has no water permeability, but lacks flexibility, which leads to destruction due to even a little bending stress. However, it is considered that the destruction of glass is not caused owing to strength of a glass material itself but caused owing to even a weak force with countless flaws on the glass substrate surface as destruction starting points. One surface with the flaws of the glass substrate is covered by a polymer as disclosed in Technical Document 1 (JP 11-329715 A), with the result that the strength against bending of the glass substrate can be remarkably improved. However, regarding a specific method of manufacturing the above combined substrate, Patent Document 1 merely describes that “a glass substrate with a thickness of about 30 μm, which can be obtained from DESAG·AG (Germany) or the like, is still extremely difficult to be treated, and is extremely easily damaged unless it is treated with extreme attention.” (p. 4, 11.31 to 34). The combined substrate has a sufficient strength. However, no description has been made of how the combined substrate is reliably manufactured. There is also no description of how the thin and fragile glass substrate is treated in the manufacturing process.

Further, in recent years, development has been made on an organic EL light emitting device which is driven by using a thin film transistor. In general, heat treatment is essential in a process of manufacturing the thin film transistor. The substrate obtained by combining glass with a polymer has high heat resistance on its surface. However, the glass differs from the polymer in thermal expansion coefficient. Thus, the substrate may be warped through heat treatment. This may interrupt the subsequent steps, and also, dimension precision is hardly obtained.

As described above, in the case where the extremely thin glass substrate is used from the first to be combined with the polymer, the damage of the glass substrate is inevitable even if it is treated with considerable attention. Thus, the expected manufacturing yield is considerably low. Further, even when the substrate is to be increased in size for obtaining, for example, a large screen display, and a large number of pieces thereof for the improvement of production efficiency, the extremely thin glass substrate with a large area itself can hardly be manufactured. Even if the manufacture of such the thin and large area glass substrate is realized, the fact that the extremely thin glass substrate is difficult to be treated in the process is easily expected. With the above-described difficulties, it has been a large problem in that valuable and excellent performances can hardly be provided with a cost appropriate to the market. Furthermore, the material obtained by simply combining the glass substrate with the polymer is extremely difficult to provide dimension precision due to the differences in thermal expansion coefficients among the respective materials in the case where the combined material is subjected to the heating step like the formation of the thin film transistor.

### SUMMARY OF THE INVENTION

In order to manufacture a flexible substrate obtained by combining glass with a polymer material in a simple and easy method, according to the present invention, a method of manufacturing an organic electronic device includes: a first step of polishing a first surface of a substrate; a second step of providing a protective layer on the first surface; a third step of removing a second surface on a side opposite to the first surface through etching to reduce the thickness of the substrate; a fourth step of inserting a layer containing a polymer material in a gap formed by opposing etching surfaces of two extremely thin substrates manufactured through the first to third steps to bond the two extremely thin substrates to each other; a fifth step of removing the protective polymer layer; and a sixth step of forming an organic electronic device on the first surface from which the protective polymer layer has been removed. In this case, a film containing as a main component an aliphatic or alicyclic polyimide resin, a polyamideimide resin, a thermosetting vinylester resin, a thermosetting bisphenol A resin, or a cardo-based resin is used as the layer containing a polymer material. Alternatively, a polymer film containing as a main component any one of polyethylene terephthalate, polyethylene naphthalate, polycarbonate, polyallylate, polyether sulfone, polysulfone, polyether imide, polyimide, polyamide, a cyclicolefinpolymer and copolymer thereof, a thermosetting vinylester resin, or a thermosetting bisphenol A resin is used. Further, a polymer containing as a component polyethylene terephthalate, polyethylene naphthalate, polycarbonate, polyallylate, polyether sulfone, polysulfone, polyether imide, polyimide, polyamide, a cyclicolefinpolymer or copolymer thereof, a thermosetting vinylester resin, or a thermosetting bisphenol A resin, acrylic resin, or phenol novolac resin may be used as a protective layer. In addition, a glass substrate having a thickness of 0.3 mm or more is used as a substrate to obtain a substrate having a thickness of 0.2 mm or less through the third step.

According to the above-mentioned method, the organic electronic device with flexibility can be formed so as to include the thin film transistor with the use of the heating step to the smooth substrate surface by the simple and easy way. The formed organic electronic device has high performance and high dimension precision, does not involve deterioration due to moisture that penetrates through the substrate, and has flexibility in the substrate. Consequently, the device with high strength is realized which is not destructed while being warped.

### BRIEF DESCRIPTION OF THE DRAWINGS

In the accompanying drawings:

FIGS. 1A to 1E are schematic diagrams showing a method of manufacturing a substrate for an organic electronic device according to the present invention; and

FIG. 2 is a schematic diagram showing an organic electronic device according to the present invention.

### DETAILED DESCRIPTION OF THE PREFERRED EMBODIMENTS

A method of manufacturing an organic electronic device of the present invention includes: a first step of polishing a first surface of a substrate; a second step of providing a protective layer on the first surface; a third step of removing a second surface on a back side of the first surface of the substrate through etching to reduce the thickness of the substrate; a fourth step of inserting a layer containing a polymer material in a gap formed by opposed etching surfaces of two extremely thin substrates manufactured through the first to third steps to bond the two extremely thin substrates to each other; a fifth step of removing the protective layer; and a sixth step of forming an organic electronic device on the first surface from which the protective layer has been removed.

The surface of the substrate on which the organic electronic device is to be formed needs to be flat. Thus, polishing treatment in the first step is important. Further, the limit of the thickness of a practical substrate capable of being introduced into the polishing step is 0.3 mm. The substrate with a thickness of 0.3 mm or more is selected, which can be formed in large area and which can be handled without damage through the steps. As to a material for the substrate, soda glass, borosilicate glass, no alkali glass, and the like can be selected depending on purposes. Here, no alkali glass is selected in order to form an inorganic electronic circuit like a thin film transistor and prevent an alkali metal from diffusing from glass.

Further, the protective layer is provided on the polished surface in the second step for the purpose of protecting the flattened surface through the subsequent steps and the purpose of holding the thinned glass substrate (reinforcing glass strength) to stably perform the subsequent steps. Examples of the materials for the protective layer include a polymer material and a material obtained by combining the polymer material with an inorganic compound. As to the form of the protective layer, the material may be coated to the substrate, or a film made of the material may be attached to the substrate. The protective layer is formed on a thick glass substrate, which does not damage the glass substrate as described above.

Next, an opposite surface of the substrate is subjected to etching with the flattened surface in a protected state, thereby reducing a thickness of the substrate. In the case of the glass substrate, a thickness thereof which exhibits flexibility depends on a glass material. A thickness of less than 0.1 mm realizes considerable flexibility. It is considered that a thickness of less than 0.2 mm realizes flexibility regarding all kinds of the glass.

The two extremely thinned glass substrates are bonded to each other such that etching surfaces thereof are opposed to each other to sandwich a layer containing a polymer material therebetween. Thus, a front and rear surfaces of the combined substrate are made of polished glass surfaces. Therefore, the respective thermal expansion amounts of the front and rear surfaces are equal to each other in the case of heat treatment. Accordingly, the inorganic circuit device such as the thin film transistor can be manufactured with high precision and without distortion on both the surfaces. As a result, the organic electronic device to be combined with the inorganic circuit device is further improved in terms of characteristics.

Here, the layer containing the polymer material is mainly composed of a polymer, and may be appropriately mixed with, for example, inorganic fine particles such as a filler. The polymer material is coated onto the substrate, or the film containing the material is attached to the substrate. At this point, the protective layer formed on the polished surface plays a role of a supporting film with respect to extremely thin glass, and prevents the substrate from being damaged through the steps. Next, in the fifth step, the protective coating or protective film, which has protected the polished surface of the substrate, is peeled and removed, thereby making the polished surface of the substrate exposed. The layer containing the polymer material adheres the two extremely thin glass substrates to each other to impart flexibility and bending strength to the substrates. Accordingly, the practical substrate for the organic electronic device is provided.

Hereinafter, further detailed description will be made on a method of manufacturing an organic electronic device according to the present invention.

### EMBODIMENT 1

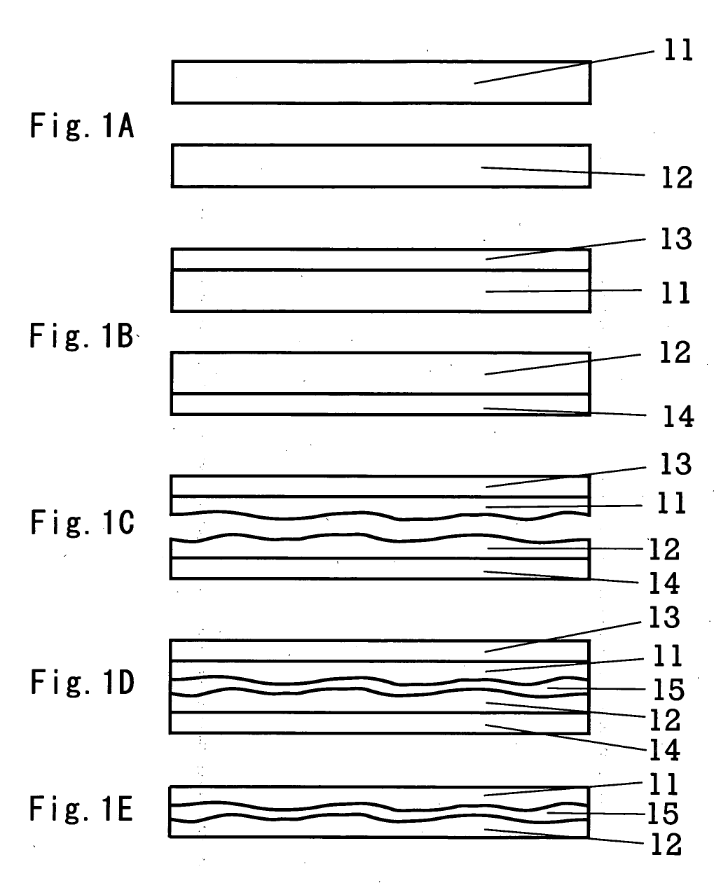

FIGS. 1A to 1E schematically show the method of manufacturing the organic electronic device in accordance with Embodiment 1 of the present invention. FIG. 1A is a sectional view showing two substrates 11 and 12. No alkali glass substrates each having a thickness of 0.5 mm are used in Embodiment 1. One of surfaces of the glass substrate is subjected to flattening treatment through polishing with the use of a wrap film or polishing material. The surface has a precision of 0.1 μm or less.

FIG. 1B is a sectional view showing a state in which protective polymer layers 13 and 14 are provided on the flattened surfaces, that is, the polished surfaces of the substrates 11 and 12, respectively. The protective polymer layer may be formed by a method such as laminating with the use of a polymer film and an adhesion layer. The polymer film may be formed of polyethylene terephthalate, polyethylene naphthalate, polycarbonate, polyarylate, polyether sulfone, polysulfone, polyether imide, or the like. Further, the adhesion layer maybe made of acrylic resin, silicon resin, or the like. The adhesion layer used here desirably loses its adhesion property due to light, heat, immersion to a solvent, or the like in order to perform the peeling step described later. In the drawing, the protective polymer layers are formed on the respective surfaces of the two substrates, which are opposite to the surfaces opposed to each other.

Next, the substrates 11 and 12, which are respectively formed with the protective polymer layers 13 and 14, are subjected to glass etching by being immersed into an etching solution such as fluoric acid, and the thickness of each of the substrates is reduced to 0.10 mm. This state is shown in FIG. 1C. In this state, glass itself is weak in strength, so the substrates are easily destructed when the protective polymer layers are to be peeled.

Subsequently, a polymer layer 15, which is mainly composed of any one of: aliphatic or cycloaliphatic polyimide resin; polyamide imide resin; thermosetting vinyl ester resin; thermosetting bisphenol A resin; or card type resin is provided between the opposed etching surfaces of the substrates 11 and 12. The substrates 11 and 12 are bonded to each other through the polymer layer 15. FIG. 1D schematically shows a section of the above state.

A solution obtained by dissolving a polymer formed through condensation polymerization of aliphatic tetracarboxylic acid and aromatic diamine into y-butyrolactone, or the like is used for the aliphatic or alicyclic polyimide resin. In order to improve adhesiveness between the solution and glass, an additive such as a coupling agent may be arbitrarily included. An example of the polyamideimide resin includes “PYROMAX (registered trademark)” manufactured by TOYOBO., LTD. and an example of the thermosetting vinyl ester resin includes “SUPERPOLYESTER SSP SERIES” manufactured by SHOWA HIGHPOLYMER CO., LTD. An example of the thermosetting bisphenol A resin includes “LIGOLITE (registered trademark) 500” manufactured by SHOWA HIGHPOLYMER CO., LTD., and an example of the cardo-based resin includes “V-259” manufactured by Nippon Steel Chemical Group. An appropriate curing treatment is conducted on each of those materials by means of thermosetting, ultraviolet curing, or the like after the materials each are applied on a substrate by means of a roll coater, bar coater, slit coater, or the like to bond two substrates. The thickness of a polymer layer 15 after bonding was 50 μm.

Next, as shown in FIG. 1E, the protective polymer layers 13 and 14 are peeled such that the polished surfaces of the substrates 11 and 12 are exposed through light, heat, or immersion to a solvent or with an auxiliary means such as a mechanical removing means. In this step, the two glass substrates are bonded to each other through the polymer layer with a thickness of 50 μm, and thus, have flexibility and bending strength to some extent. Therefore, the destruction of the two glass substrates is not found in the peeling step.

The flexible substrate for the organic electronic device is formed through the above steps. The substrate is light and strong against bending, and keeps its flat surface on the side of the polished surface.

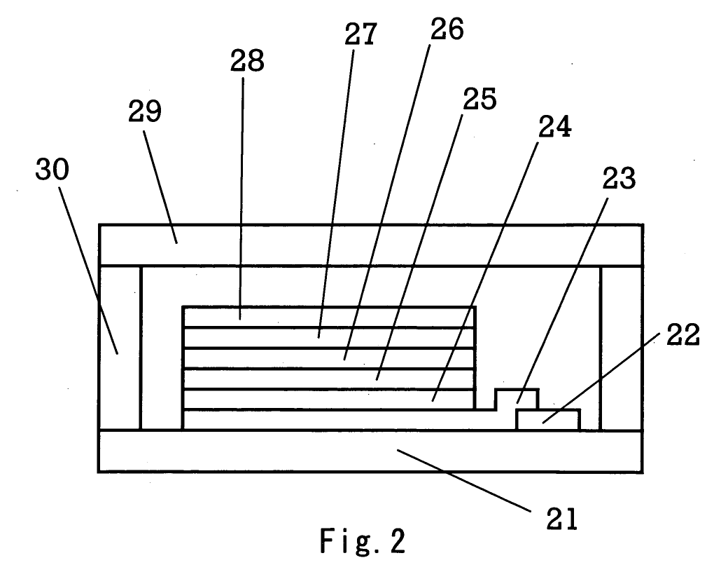

Next, FIG. 2 shows an organic EL light emitting device having a thin film transistor, which is an example of the organic electronic device manufactured by using the substrate according to the present invention. In FIG. 2, a substrate 21 is formed by the method explained with reference to FIGS. 1A to 1E. A TFT 22 is formed on the substrate 21. The TFT 22 is formed through the following steps. First, an amorphous silicon layer, which is formed by CVD, is subjected to patterning through laser annealing to form a polysilicon layer. A temperature of the substrate surface rises to 200° C. or more at the time of CVD and laser annealing. However, in Embodiment 1, CVD and laser annealing are performed as in the same manner as the film deposition to the glass substrate since the film deposition surface is covered with glass. Also, the rear surface of the substrate is covered with glass, so there is no difference in thermal expansion coefficient between the front and rear surfaces. Therefore, defects such as curl toward one surface of the substrate are not found. Next, a gate insulating film made of SiO₂ or the like is formed on the polysilicon layer through CVD or the like. This step involves the same problem as in the formation of the polysilicon layer, but the problem does not arise in Embodiment 1. Subsequently, a gate electrode, source electrode, and drain electrode are formed, thereby forming the TFT. Although many heating steps are required in manufacturing the TFT as described above, the TFT element is minute, and needs to have high stability in terms of dimensions. In Embodiment 1, the minute TFT with excellent characteristics can be formed by using the lightweight and thin substrate.

Next, an anode 23 formed of a transparent conductive coating composed of ITO, IZO, or the like by means of a method such as a spattering, vapor deposition, or CVD is formed such that the anode 23 is connected to a source electrode of a TFT 22. The surface on which the anode is formed is a glass surface, and hence the anode was able to be formed with no requirement of specific treatment other than washing and cleaning treatment. A hole injecting layer 24 composed of copper phthalocyanine or an aromatic amine and a hole transporting layer 25 composed of an A-NPD or TPD derivative or the like, which is also an aromatic amine are laminated on the anode 23 by means of vacuum evaporation. A layer is formed as a emission layer 26 thereon by means of co-evaporation, in which a host material composed of, for example, a metal complex of a 8-hydroxyquinoline derivative such as Alq3, BAlq3, or Bebq2 contains as a dopant a luminous emission pigment such as perylene, quinacridone, coumarin, rubrene, or DCJTB. In addition, an electron transporting layer 27 such as Alq3 or Bebq2 and further a cathode 28 laminating Al on a LiF thin film each are formed by means of vacuum evaporation.

Then, the resultant is bonded with a flexible substrate 29, which is obtained by combining glass with a polymer material, through a sealing agent 30 for sealing, with the result that the organic EL light emitting device is manufactured. The organic EL light emitting device shows a stable light emitting characteristic without deterioration due to moisture penetration although it is manufactured by the simple and practical method as described above. Accordingly, there is provided the organic EL light emitting device, which is thin and light, has flexibility to some extent, and is excellent in portability.

### EMBODIMENT 2

Description will be made of Embodiment 2 with reference to FIGS. 1A to 1E as in Embodiment 1. The substrates 11 and 12 shown in FIG. 1A each are composed of a no alkali glass substrate with a thickness of 0.4 mm. At least one of surfaces of the glass substrate is subjected to flattening treatment through polishing with the use of the wrap film or polishing material, and thus, has a precision of 0.1 μm or less.

In FIG. 1B, formed on the polished surface of each of the substrates 11 and 12 is a coating film composed of a polymer including, as its main constituent, any one of polyimide, polyamide, cyclic olefin polymer, cyclic olefin copolymer, thermosetting vinyl ester resin, thermosetting bisphenol A resin, acrylic resin, and phenolic novolac resin. The polymer is composed of a solution or precursor solution, and is applied onto the substrate by means of a roll coater, bar coater, slit coater, or the like. The applied polymer is appropriately subjected to hardening treatment through dry hardening, thermal curing, ultraviolet curing, or the like. As a result, the protective polymer layers 13 and 14 are formed. The thickness of each of the protective polymer layers 13 and 14 is set to 100 μm. However, there is no limitation placed on the thickness as long as the thickness is enough to sufficiently reinforce the thinned glass substrate. The protective polymer layer used here is desirably dissolved or peeled with ease through light, heat, immersion to a solvent, or the like in order to easily perform the peeling step described later. In FIG. 1B, the protective polymer layers are formed on the opposite side to the respective opposed surfaces of the two substrates.

In FIG. 1C, Substrates 11 and 12 each having protecting polymers 13 and 14 formed are immersed into an etching liquid such as hydrofluoric acid, and then are glass-etched to thin the thickness of each of the substrates to be 0.1 mm. Hardness of glass itself is weak in this sate. Therefore the substrates each may be broken easily when the protective layer is continued to be detached.

In FIG. 1D, a polymer layer 15 is formed by sandwiching a polymer film containing as a main component any one of polyethylene terephthalate, polyethylene naphthalate, polycarbonate, polyallylate, polyether sulfone, polysulfone, polyether imide, polyimide, polyamide, a cyclicolefinpolymer or copolymer thereof, a thermosetting vinylester resin, and a thermosetting bisphenol A resin between two glass substrates by means of an adhesive while the etching surface of the etched substrate 11 and the etching surface of the etched substrate 12 are faced each other. An example of a polyethylene terephthalate film includes “TEFLEX (registered trademark)” manufactured by TEIJIN LIMITED, an example of a polyethylene naphthalate film includes “TEONEX (registered trademark)” manufactured by TEIJIN LIMITED, and an example of a polycarbonate includes “PANLITE (registered trademark)” manufactured by TEIJIN LIMITED. An example of a polyallylate film includes “CRYSTALATE (registered trademark)” manufactured by Kaneka Corporation, an example of a polyether sulfone film includes “SUMILITE (registered trademark) FS-1300” manufactured by SUMITOMO BAKELITE Co., Ltd., and an example of a polysulfone film includes “SUMILITE (registered trademark) FS-1200” manufactured by SUMITOMO BAKELITE Co., Ltd. An example of a polyether imide film includes “SUPERIO (registered trademark)” manufactured by Mitsubishi Plastics, Inc., an example of a polyimide film includes fluorinated polyimide manufactured by Kaneka Corporation, and an example of a polyamide film includes a nylon film. An example of a cyclicolefinpolymer or copolymer thereof film includes “ARTON (registered trademark)” manufactured by JSR or “ZEONOR (registered trademark)” manufactured by ZEON CORPRATION. In addition, an example of a thermosetting vinylester resin film includes “LIGOLITE (registered trademark)” manufactured by SHOWA HIGHPOLYMER CO., LTD. and an example of a thermosetting bisphenol A resin film includes “LIGOLITE (registered trademark) 500” manufactured by SHOWA HIGHPOLYMER CO., LTD. Those materials each are bonded between substrates via an acrylic adhesive or silicon-based adhesive. An adhesive to be used is preferably an adhesive that has an excellent adhesiveness. The film sandwiched between the substrates is the polymer layer 15 and the thickness of the polymer layer 15 was 100 μm.

In FIG. 1E, the polished surfaces of the substrates 11 and 12 are exposed by peeling the protective polymer layers 13 and 14 through light, heat, or immersion to a solvent or with the use of the auxiliary means such as the mechanical removing means. In this step, the two glass substrates hold the polymer film with a thickness of 100 μm therebetween. This imparts flexibility and strength against bending to the substrates. Therefore, the destruction of the glass substrate is not found in the peeling step.

The flexible substrate for the organic electronic device is formed through the above-described steps. The substrate is light and strong against bending, and has the flat surface on the polished surface side. Further, when the organic EL light emitting device is manufactured as in Embodiment 1, the same effect as in Embodiment 1 is obtained.

The organic EL light emitting device as an example of the organic electronic device described in the above embodiments can be the mainstay of a man-machine interface of the future electronic device such as a curved light source of a car fascia board or a portable ubiquitous display, which makes the best use of lightweight property and thinness of the organic EL light emitting device, for example, a ground-wave digital receiving device, portable browser, or a monitor of a digital camera/video camera.

What is claimed is:

1. A method of manufacturing an organic electronic device, comprising:
a first step of polishing a first surface of a substrate;
a second step of providing a protective layer on the first surface;
a third step of removing a second surface on a back side of the first surface through etching to reduce the thickness of the substrate;
a fourth step of inserting a layer containing a polymer material in a gap formed by opposing etching surfaces of two extremely thin substrates manufactured through the first to third steps to bond the two extremely thin substrates to each other;
a fifth step of removing the protective layer; and
a sixth step of forming an organic electronic device on the first surface from which the protective layer has been removed.

2. A method of manufacturing an organic electronic device according to claim 1, wherein the substrate comprises a glass substrate with a thickness of 0.3 mm or more, and is processed to have a thickness of 0.2 mm or less in the third step.

3. A method of manufacturing an organic electronic device according to claim 1, wherein the layer containing the polymer material comprises a film containing as a main component any one of an aliphatic polyimide resin, alicyclic polyimide resin, a polyamideimide resin, a thermosetting vinylester resin, a thermosetting bisphenol A resin, and a cardo-based resin, and the layer is formed by coating.

4. A method of manufacturing an organic electronic device according to claim 1, wherein the layer containing the polymer material comprises a film containing as a main component any one of polyethylene terephthalate, polyethylene naphthalate, polycarbonate, polyallylate, polyether sulfone, polysulfone, polyether imide, polyimide, polyamide, a cyclicolefinpolymer or copolymer thereof, a thermosetting vinylester resin, and a thermosetting bisphenol A resin, and the polymer layer is bonded on the second surface by means of an additive.

5. A method of manufacturing an organic electronic device according to claim 1, wherein the protective layer comprises a protective polymer layer containing as a main component any one of polyethylene terephthalate, polyethylene naphthalate, polycarbonate, polyallylate, polyether sulfone, polysulfone, polyether imide, polyimide, polyamide, a cyclicolefinpolymer or copolymer thereof, a thermosetting vinylester resin, a thermosetting bisphenol A resin, an acrylic resin, and a phenol novolac resin.

6. A method of manufacturing an organic electronic device according to claim 1, wherein the organic electronic device formed on the first surface from which the protective layer is removed is an organic EL light emitting device including a thin film transistor.
